(19) United States
(12) Patent Application Publication
(10) Pub. No.: US 2024/0421015 A1
(43) Pub. Date: Dec. 19, 2024

(54) SEMICONDUCTOR PACKAGE AND METHOD FOR FORMING THE SAME

(71) Applicant: JCET STATS ChipPAC Korea Limited, Incheon (KR)

(72) Inventors: SeungHyun LEE, Incheon (KR); YeJin PARK, Incheon (KR); HeeSoo LEE, Incheon (KR); HyunSu TAK, Incheon (KR); SangJun PARK, Incheon (KR)

(21) Appl. No.: 18/746,135

(22) Filed: Jun. 18, 2024

(30) Foreign Application Priority Data
Jun. 19, 2023 (CN) 202310726967.7

(51) Int. Cl. H01L 23/31; H01L 21/56; H01L 23/00; H01L 23/14; H01L 23/552; H01L 25/16; H01R 12/52

(52) U.S. Cl. CPC H01L 23/3121; H01L 21/56; H01L 23/14; H01L 23/552; H01R 12/52; H01L 24/16; H01L 25/16; H01L 2224/16245; H01L 2924/1815

(57) ABSTRACT

A semiconductor package is disclosed. The semiconductor package comprises: a metal shim, a package substrate attached onto a front side of the metal shim, wherein the package substrate comprises an opening that passes therethrough; one or more electronic components mounted on the package substrate; an encapsulant layer partially formed on the package substrate to expose a region of the package substrate and the opening of the package substrate, wherein the encapsulant layer encapsulates the one or more electronic components on the package substrate; a first connector mounted in the exposed region of the package substrate; a second connector mounted in the encapsulant layer and on the package substrate; and a magnet mounted in the opening of the package substrate and extending from the metal shim through the package substrate and the encapsulant layer.

### TECHNICAL FIELD

The present application generally relates to semiconductor technology, and more particularly, to a semiconductor device, in particular a semiconductor package, and a method for forming a semiconductor package.

### BACKGROUND OF THE INVENTION

Nowadays, smart watches require a broad package portfolio including among other sensors, connectivity units, security units, and embedded processing units for the purposes such as comfort, compact, fashionable, low power consumption, and performance efficiency.

Thus, there is a need for further improvement of semiconductor packages for smart watches.

### SUMMARY OF THE INVENTION

An objective of the present application is to provide a semiconductor package with embedded sensor processing modules.

According to an aspect of the present application, a semiconductor package is provided. The semiconductor package comprises: a metal shim, a package substrate attached onto a front side of the metal shim, wherein the package substrate comprises an opening that passes therethrough; one or more electronic components mounted on the package substrate; an encapsulant layer partially formed on the package substrate to expose a region of the package substrate and the opening of the package substrate, wherein the encapsulant layer encapsulates the one or more electronic components on the package substrate; a first connector mounted in the exposed region of the package substrate; a second connector mounted in the encapsulant layer and on the package substrate; and a magnet mounted in the opening of the package substrate and extending from the metal shim through the package substrate and the encapsulant layer.

According to another aspect of the present application, a semiconductor package is provided. The semiconductor package comprises: a metal shim, a package substrate attached onto a front side of the metal shim, wherein the package substrate comprises an opening that passes therethrough; one or more electronic components mounted on the package substrate; an encapsulant layer formed on the package substrate to encapsulate the one or more electronic components, wherein the opening of the package substrate is exposed from the encapsulant layer; a first connector and a second connector mounted in the encapsulant layer and on the package substrate; and a magnet mounted in the opening of the package substrate and extending from the metal shim through the package substrate and the encapsulant layer.

It is to be understood that both the foregoing general description and the following detailed description are exemplary and explanatory only, and are not restrictive of the present application. Further, the accompanying drawings, which are incorporated in and constitute a part of this specification, illustrate embodiments of the present application and together with the description, serve to explain principles of the present application.

### BRIEF DESCRIPTION OF DRAWINGS

The drawings referenced herein form a part of the specification. Features shown in the drawing illustrate only some embodiments of the present application, and not of all embodiments of the present application, unless the detailed description explicitly indicates otherwise, and readers of the specification should not make implications to the contrary.

FIG. 1A to FIG. 1C illustrate top, perspective, and cross-sectional views of a semiconductor package according to an embodiment of the present application.

FIGS. 2A to 2I illustrate, in cross-sectional views, various steps of a process for forming the semiconductor package according to the embodiment shown in FIG. 1A to FIG. 1C.

FIG. 3A to FIG. 3C illustrate top, perspective and cross-sectional views of a semiconductor package according to another embodiment of the present application.

FIG. 4A to 4I illustrate, in cross-sectional views, various steps of a process for forming the semiconductor package according to the embodiment shown in FIG. 3A to FIG. 3C.

FIG. 5A to FIG. 5C illustrate a variant of the semiconductor package shown in FIG. 1A to FIG. 1C.

FIG. 6A to FIG. 6C illustrate a variant of the semiconductor package shown in FIG. 3A to FIG. 3C.

The same reference numbers will be used throughout the drawings to refer to the same or like parts.

### DETAILED DESCRIPTION OF THE INVENTION

The following detailed description of exemplary embodiments of the present application refers to the accompanying drawings that form a part of the description. The drawings illustrate specific exemplary embodiments in which the present application may be practiced. The detailed description, including the drawings, describes these embodiments in sufficient detail to enable those skilled in the art to practice the present application. Those skilled in the art may further utilize other embodiments of the present application, and make logical, mechanical, and other changes without departing from the spirit or scope of the present application. Readers of the following detailed description should, therefore, not interpret the description in a limiting sense, and only the appended claims define the scope of the embodiment of the present application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

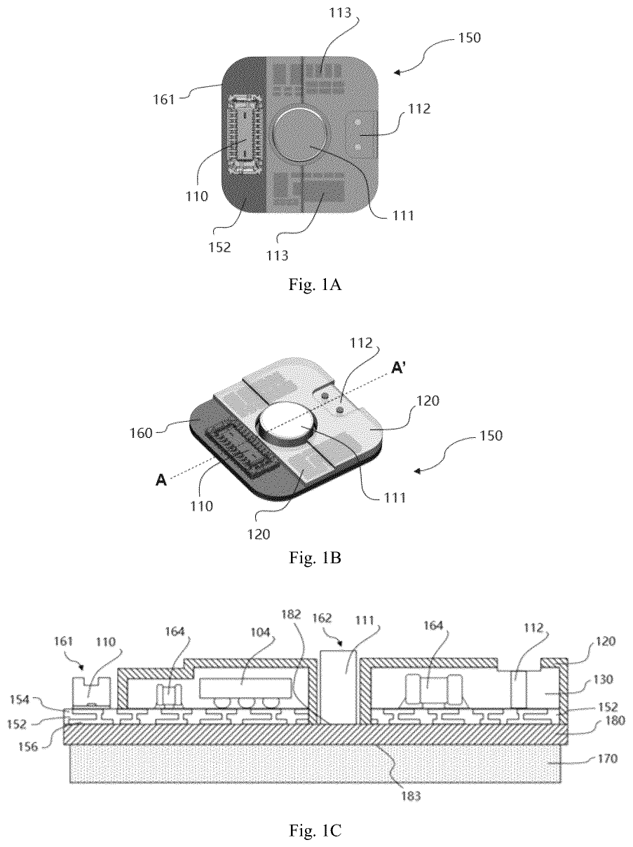

FIGS. 1A to 1C illustrate top, perspective, and cross-sectional views of a semiconductor package 150 according to an embodiment of the present application. FIG. 1C is the cross-section view of the semiconductor package 150 along line AA′ in FIG. 1B. In the embodiment, the semiconductor package 150 is formed of a square or rectangular shape with rounded corners, which can fit for a smart watch or other similarly shaped electronic devices.

As shown in FIGS. 1A to 1C, the semiconductor package 150 includes a metal shim 180 and a package substrate 152 attached onto a front side 182 of the metal shim 180. The substrate 152 may include one or more insulating layers 154 interleaved with one or more conductive layers 156. The insulating layers 154 may include a core insulating board in one embodiment, with conductive layers 156 patterned over its top and/or bottom surfaces, e.g., a copper-clad laminate substrate. The conductive layers 156 may also include conductive vias through the insulating layers 154 to electrically couple the conductive layers 156. In the embodiment, the package substrate 152 includes an opening 162 configured for housing a magnet 111. For example, the opening 162 can be formed at a center of the package substrate 152. The opening 162 may be a through hole that passes through the package substrate 152, such that the metal shim 180 can be exposed from the package substrate 152 through the opening 162. In some embodiments, the opening 162 may have a circular shape, a square shape, a rectangular shape, a hexagonal shape, or any other suitable shape, when viewed from the top. Further, the magnet 111 received within the opening 162 may have a shape that is the same as or similar to that of the opening 162. It can be appreciated that any suitable magnet arrangements can be used in the semiconductor package 150, for example, a magnet array with two or more magnets can be used in some alternative embodiments.

The semiconductor package 150 may include any electronic components desired to be mounted to or disposed over the package substrate 152 and electrically connected to the conductive layers 156. These electronic components may be further packaged within the semiconductor package 150 and electrically coupled to other external devices through respective connectors which are also mounted on the base substrate 152. In this way, multiple individual functional modules or circuits can be integrated on the single metal shim 180.

In the embodiment shown in FIG. 1C, a semiconductor die 104 such as a sensor chip, a memory chip, a signal processing chip, a micro processing unit, etc., and discrete electronic components 164 are mounted on the package substrate 152. The discrete electronic components 164 can be passive components such as capacitors, resistors, or inductors, active components such as diodes or transistors, or any other desired electronic components. Furthermore, a first connector 110 being a board-to-board (B2B) connector, a second connector 112 being a metal bar connector (e.g., a pin type connector) are also mounted on the base substrate 152. These connectors 110 and 112 can be electrically coupled with the electronic components through the base substrate 152, or particularly through the conductive layers and vias in the base substrate 152.

An encapsulant layer 130 is partially formed on the package substrate 152 to encapsulate and protect the electronic components. The encapsulant layer 130 does not cover an entirety of the front surface of the package substrate 152, rather, a region of the package substrate 152 is exposed from the encapsulant layer 130, which is shown as the exposed region 161. The first connector 110 is mounted on the substrate 152 in the exposed region 161, i.e., the first connector 110 is not encapsulated by the encapsulant layer 130. Differently, the second connector 112 is formed in the encapsulant layer 130. In the embodiment, the first connector 110 and the second connector 112 are mounted on the base substrate 152 on two opposite sides of the magnet 111.

Furthermore, the encapsulant layer 130 is generally not filled in the opening 162 so that it can expose the opening 162 of the package substrate 152, leaving the space for receiving the magnet 111. The magnet 111 is mounted in the opening 162 of the package substrate 152 and extending from the metal shim 180 to a position above the encapsulant layer 130, i.e., the magnet 111 passes through the package substrate 152 and the encapsulant layer 130. In the example, the encapsulant layer 130 has a step adjacent to the exposed region 161 so that a top surface of the stepped portion of the encapsulant layer 130 can be generally flush with a top surface of the first B2B connector 110. As such, it is easier to connect a connector of an external device to the first B2B connector 110.

The first connector 110 may be physically and electrically coupled to the conductive layers of the base substrate 152 through solder bumps or other similar conductive structures. In some embodiments, the first connector 110 is used to be connected to an external microcontroller or to another adjacent electronic package or device so that semiconductor die 104 can communicate with the other device through the first connector 110. In the example, the encapsulant layer 130 is at least partially covered by a shielding layer 120 such as a metal layer. The shielding layer 120 can shield external electromagnetic interferences (EMI) from the electronic components encapsulated by the encapsulant layer 130. Furthermore, the encapsulant layer 130 and the shielding layer 120 are both patterned close to the second connector 112 to expose a top surface of the metal bars of the second connector 112. In this way, the second connector 112 can be electrically connected to another connector of an external device.

In addition to the B2B connector 110, the semiconductor package 150 may include one or more another electronic components in the exposed region 161, which may have a different requirement on EMI shielding, for example due to their respective functions in the semiconductor package. In some embodiments, the uncovered electronic component may include antennas or other components that do not require EMI shielding.

A sensor module170 may be disposed on a back side 183 of the metal shim 180, which is opposite to the package substrate 152. In some embodiments, the sensor module 170 can be an optical sensor module. For example, the optical sensor module may include one or more infrared sensors, which can collect physiological information of a user wearing an electronic product incorporating the semiconductor package 150. For example, the optical sensor module may serve as a cardiotachometer, or a pulse oximeter. Since it is disposed on the back side 183 of the metal shim 180, the sensor module 170 can be closer to the body of the user, and preferably in contact with the skin of the user for collection of physiological information.

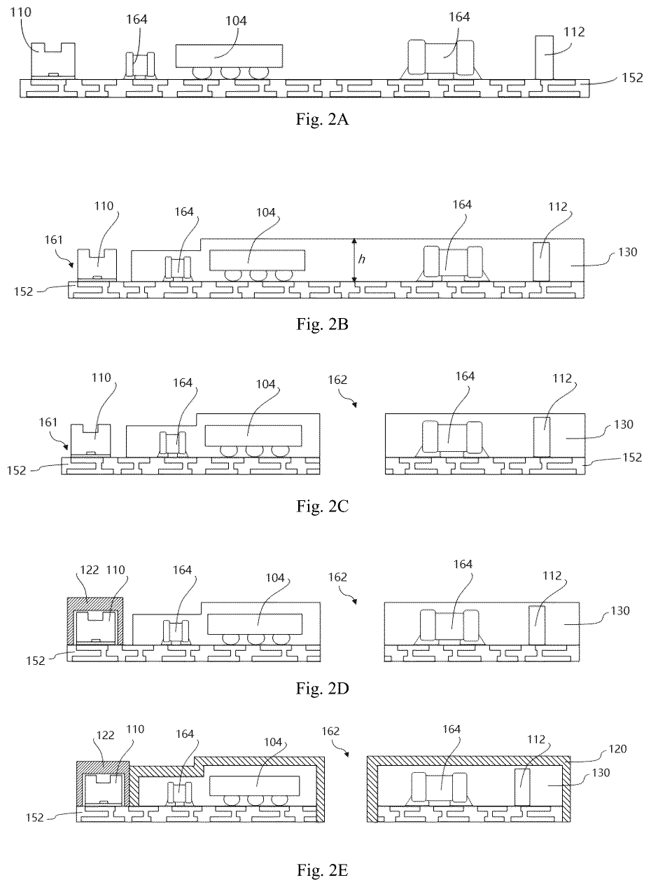

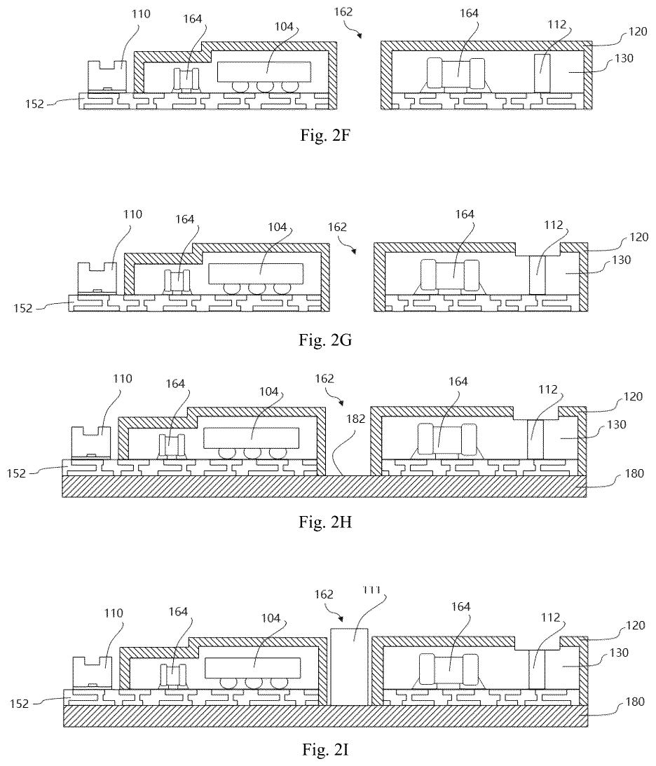

FIG. 2A to 2I illustrate a process for forming the semiconductor package 150 shown in FIG. 1A to 1C.

As shown in FIG. 2A, a package substrate 152 is provided, with various components mounted thereon. For example, a semiconductor die 104 is mounted on the substrate 152 along with discrete electronic components 164, for example using surface mounting techniques. The package substrate 152 may include one or more laminated layers of polytetrafluoroethylene pre-impregnated, FR-4, FR-1, CEM-1, or CEM-3 with a combination of phenolic cotton paper, epoxy, resin, woven glass, matte glass, polyester, and other reinforcement fibers or fabrics. The substrate can also be a multi-layer flexible laminate, ceramic, copper clad laminate, or glass. The package substrate 152 may further include one or more interconnection structures such as contact pads, conductive traces, and conductive vias configured as necessary to implement a desired signal routing. The semiconductor die 104 may include a digital signal processor (DSP), a microcontroller, a microprocessor, a network processor, a power management processor, an audio processor, a video processor, an RF circuit, a wireless baseband system-on-chip (SoC) processor, a sensor, a memory controller, a memory device, an application specific integrated circuit, etc.

Furthermore, a first connector 110 which may be a B2B connector and a second connector 112 which may be a metal bar connector are mounted onto the base substrate 152. In the embodiment, the first connector 110 and the second connector 112 are mounted on the package substrate 152 at two opposite sides to allow for more space for their connection with respective external connectors.

As shown in FIG. 2B, an encapsulant layer 130 is then formed partially on the base substrate 152 by molding to cover the semiconductor die 104, the electronic components 164 and the metal bar connector 112, while leaving uncovered the B2B connector 110, forming an exposed region 161 adjacent to the encapsulant layer 130. The encapsulant layer 130 may be deposited on the package substrate 152 using compressive molding, transfer molding or liquid encapsulant molding, for example. In some embodiments, the encapsulant layer 130 may be made of a polymer composite material such as epoxy resin with filler, epoxy acrylate with filler, or polymer with proper filler, for example. The encapsulant layer 130 provides structural support and/or protect the electronic components from external elements or contaminants. In some embodiments, a grinding operation can be performed on the encapsulant layer 130 to reduce a thickness of the encapsulant layer 130 and, optionally, to expose the electronic components if desired. In the embodiment, the encapsulant layer 130 is partially stepped adjacent to the exposed region 161 so that a top surface of the stepped portion of the encapsulant layer 130 can be generally flush with a top surface of the first B2B connector 110. In some embodiments, the encapsulant layer 130 may be formed using an injection molding process where a mold cover or chase (not shown) is used. During the injection molding process, the mold cover may cover the electronic components and accommodate them within a mold cavity.

Next, as illustrated in FIG. 2C, laser ablation is applied to the encapsulant layer 130 and to the package substrate 152 to form an opening 162 that passes through the encapsulant layer 130 and to the package substrate 152. Although not shown in FIG. 2C, the opening 162 occupies only a portion of the package substrate 152 so that the package substrate 152 still maintains as a single piece. Also, in some embodiments, during most steps of the manufacturing process, the package substrate 152 may be held by a carrier such as a carrier tape or a carrier platform, to facilitate the various operations thereon.

In the step illustrated in FIG. 2D, a deposition mask 122, for example in the form of a cap and in particular made of metal, is attached to the package substrate 152 in case a shielding layer 120 needs to be applied thereto in a next step illustrated in FIG. 2E. As shown in FIG. 2E, if needed, the shielding layer 120 can be deposited onto the encapsulant layer 130 and on the package substrate 152 uncovered by the deposition mask 122. Particularly, the opening 162 may not be deposited with the shielding layer 120. The shielding layer 120 can shield EMI induced to or generated by the electronic components. The shielding layer 120 may be formed by depositing a conductive material such as Al, Cu, Sn, Ni, Au, Ag, or any other suitable material for electromagnetic interference (EMI) shielding, in particular by sputtering or spray coating. In a variant, other similar chemical or physical vapor deposition process can be used to form the shielding layer 120.

In a next step as illustrated in FIG. 2F, the deposition mask 123 is detached from the package substrate 102. Next, laser ablation is then applied to expose the metal bar of the second connector 112 as illustrated in FIG. 2G.

In next steps illustrated in FIGS. 2H and 2I, surface-mount technology is applied to attach the package substrate 152 on a front side 182 of a metal shim 180 and to further dispose a magnet 111 in the opening 162 on the same side 182 of the metal shim 180. As such, the semiconductor package is formed.

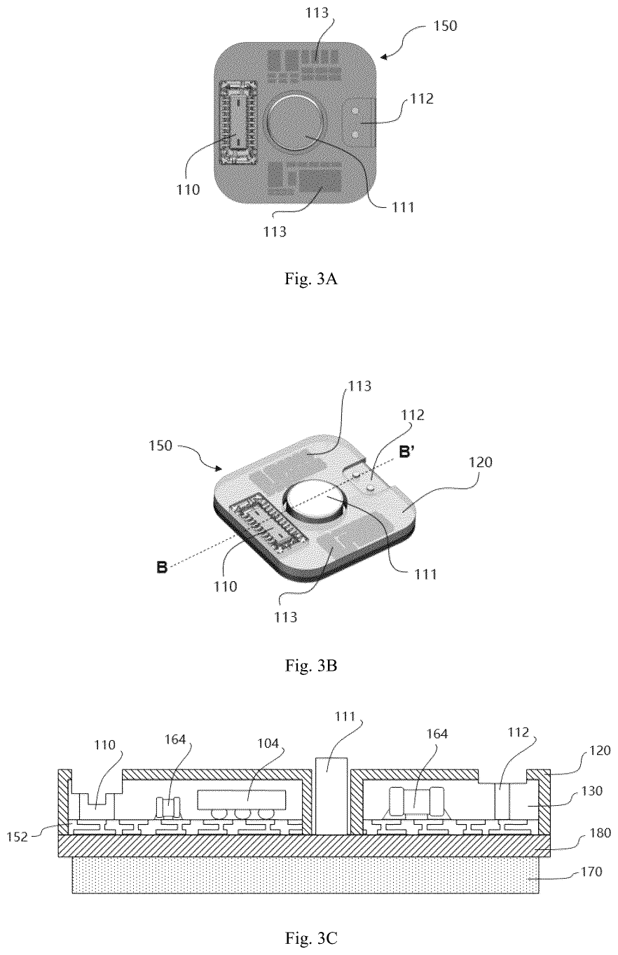

Various modifications may be made to the semiconductor package shown in FIGS. 1A to 1C. For example, a type and location of any of the connectors may change, or more electronic components may be mounted on the package substrate. FIGS. 3A to 3C, FIGS. 5A to 5C, and FIGS. 6A to 6C illustrate three exemplary semiconductor packages according to some other embodiment of the present application.

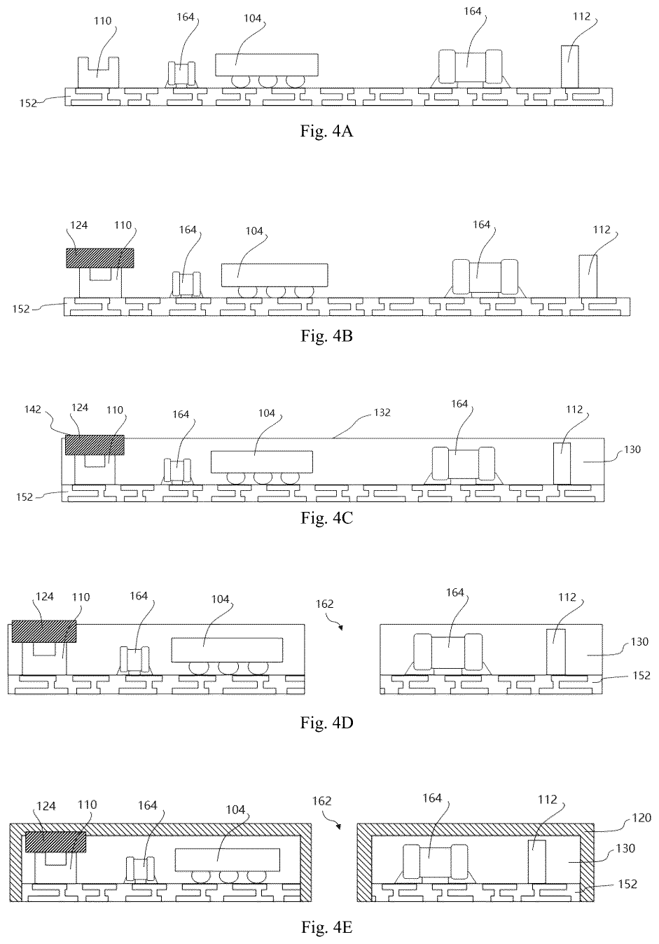

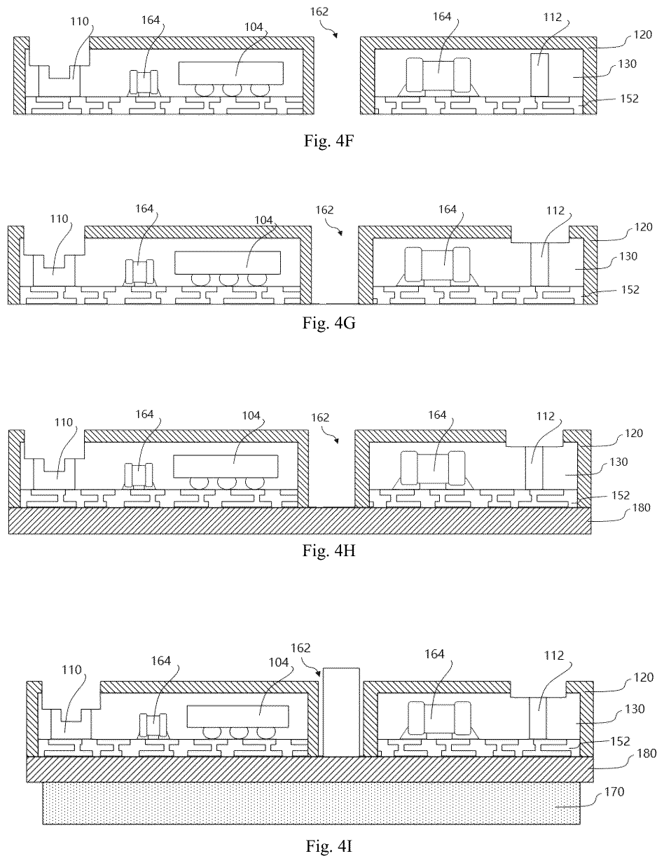

The variant of the semiconductor package illustrated in FIGS. 3A to 3C differs from the embodiment of FIGS. 1A to 1C in that the B2B connector 110 is situated within the encapsulant layer 130, rather than in the exposed region 161 shown in FIG. 1C. FIGS. 4A to 4I illustrate the process for forming the semiconductor package shown in FIGS. 3A to 3C. As illustrated in FIGS. 4B and 4C, a mask tape 124 is disposed on the B2B connector 110 before the encapsulant layer 130 is deposited. Then as illustrated in FIGS. 4C to 4E, the mask tape 124 is maintained on the B2B connector 110 when the encapsulant layer 130 is deposited on the entire surface of the substrate 152 and the shielding layer 120 is deposited on the encapsulant layer 130. In some embodiment, stepped molding as in the embodiment of FIG. 3A to 3C can also be used. In order to expose the B2B connector 110, the mask tape 124 is detached from the B2B connector 110, along with the shielding layer or optionally the encapsulant layer over the mask tape 124, as is illustrated in FIG. 4F.

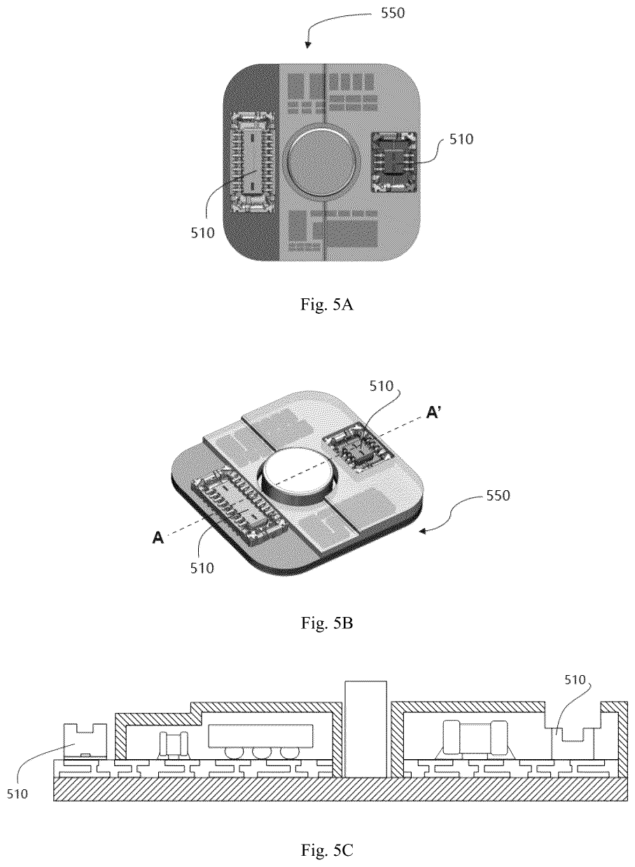

The variant 550 of the semiconductor package illustrated in FIGS. 5A to 5C differs from the embodiment of FIGS. 1A to 1C in that the metal bar connector 112 in FIG. 1C is replaced with a B2B connector 510 in FIG. 5C. That is to say, two connectors 510 are mounted on a package substrate of the semiconductor package 550, including one being encapsulated by an encapsulant layer and the other one being exposed from the encapsulant layer. It can be appreciated one or more additional connectors may be mounted on the package substrate.

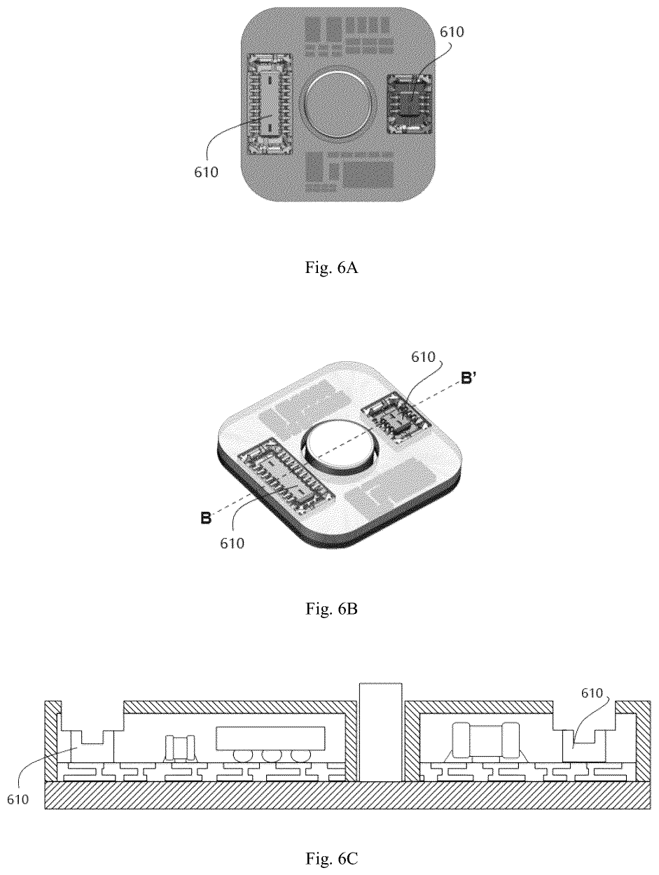

Similarly, the variant 650 of the semiconductor package illustrated in FIGS. 6A to 6C differs from the embodiment of FIGS. 1A to 1C in that the metal bar connector 112 in FIG. 1C is replaced with a B2B connector 610 in FIG. 6C. That is to say, two connectors 610 are mounted on a package substrate of the semiconductor package 650, both of which are encapsulated by an encapsulant layer. In an example, the two connectors 610 may be used for connection with different components or devices external to the semiconductor package. For example, one of the two connectors 650 may be connected to a micro control unit or other control modules of an electronic product, while the other of the two connectors 650 may be connected to a sensor module or other functional modules.

The discussion herein included numerous illustrative figures that showed various portions of a semiconductor device and a method for forming such semiconductor device. For illustrative clarity, such figures did not show all aspects of each example package. Any of the example package and/or methods provided herein may share any or all characteristics with any or all other packages and/or methods provided herein.

Various embodiments have been described herein with reference to the accompanying drawings. It will, however, be evident that various modifications and changes may be made thereto, and additional embodiments may be implemented, without departing from the broader scope of the present application as set forth in the claims that follow. Further, other embodiments will be apparent to those skilled in the art from consideration of the specification and practice of one or more embodiments of the present application disclosed herein. It is intended, therefore, that this application and the examples herein be considered as exemplary only, with a true scope and spirit of the present application being indicated by the following listing of exemplary claims.

1. A semiconductor package, comprising:
a metal shim,
a package substrate attached onto a front side of the metal shim, wherein the package substrate comprises an opening that passes therethrough;
one or more electronic components mounted on the package substrate;
an encapsulant layer partially formed on the package substrate to expose a region of the package substrate and the opening of the package substrate, wherein the encapsulant layer encapsulates the one or more electronic components on the package substrate;
a first connector mounted in the exposed region of the package substrate;
a second connector mounted in the encapsulant layer and on the package substrate; and
a magnet mounted in the opening of the package substrate and extending from the metal shim through the package substrate and the encapsulant layer.

2. The semiconductor package of claim 1, wherein the first connector is a board to board connector.

3. The semiconductor package of claim 1, wherein the second connector is a board to board connector or a metal bar connector.

4. The semiconductor package of claim 1, wherein the opening is at a center of the package substrate.

5. The semiconductor package of claim 1, further comprising a shielding layer partially formed over the encapsulant layer to expose the second connector.

6. The semiconductor package of claim 1, further comprising a sensor module mounted on a back side of the metal shim.

7. The semiconductor package of claim 1, wherein the first connector and the second connector are disposed at two opposite sides of the magnet.

8. A semiconductor package, comprising:
a metal shim,
a package substrate attached onto a front side of the metal shim, wherein the package substrate comprises an opening that passes at least partially therethrough;
one or more electronic components mounted on the package substrate;
an encapsulant layer formed on the package substrate to encapsulate the one or more electronic components, wherein the opening of the package substrate is exposed from the encapsulant layer;
a first connector and a second connector mounted in the encapsulant layer and on the package substrate; and
a magnet mounted in the opening of the package substrate and extending from the metal shim through the package substrate and the encapsulant layer.

9. (canceled)

10. (canceled)

11. The semiconductor package of claim 8, wherein the opening is at a center of the package substrate.

12. The semiconductor package of claim 8, further comprising a shielding layer partially formed over the encapsulant layer to expose the first connector and the second connector.

13. The semiconductor package of claim 8, further comprising a sensor module mounted on a back side of the metal shim.

14. The semiconductor package of claim 8, wherein the first connector and the second connector are disposed at two opposite sides of the magnet.

15. A method for forming a semiconductor package, comprising:
providing a package substrate comprising electronic components mounted on the package substrate, the electronic components comprising a first connector and a second connector;
forming an encapsulant layer on the package substrate which covers the second connector but leaves uncovered the first connector;
forming an opening through the encapsulant layer and through the package substrate;
laser ablating a portion of the encapsulant layer over the second connector to expose the second connector;
attaching the package substrate to a front side of a metal shim; and
mounting a magnet on the metal shim in the opening.

16. The method of claim 15, further comprising: attaching a sensor module on a back side of the metal shim.

17. The method of claim 15, after forming an opening, the method further comprising: forming a shielding layer on the encapsulant layer.

18. The method of claim 15, wherein the first connector is a board to board connector, and the second connector is a board to board connector or a metal bar connector.

19. A method for forming a semiconductor package, comprising:
providing a package substrate comprising electronic components mounted on the package substrate, the electronic components comprising a first connector and a second connector;
placing a mask tape on the first connector;
forming an encapsulant layer on the package substrate to cover the electronic components;
forming an opening through the encapsulant layer and through the package substrate;
detaching the mask tape from the first connector to expose the first connector from the encapsulant layer;
laser ablating a portion of the encapsulant layer over the second connector to expose the second connector;
attaching the package substrate to a front side of a metal shim; and
mounting a magnet on the metal shim in the opening.

20. The method of claim 19, further comprising: attaching a sensor module on a back side of the metal shim.

21. The method of claim 19, after forming an opening, the method further comprising: forming a shielding layer on the encapsulant layer.

22. The method of claim 19, wherein the first connector is a board to board connector, and the second connector is a board to board connector or a metal bar connector.
